(19) United States
(12) Patent Application Publication
(10) Pub. No.: US 2025/0015132 A1
(43) Pub. Date: Jan. 9, 2025

(54) SEMICONDUCTOR STRUCTURE WITH AIR SPACER AND METHOD FOR FORMING THE SAME

(71) Applicant: Taiwan Semiconductor Manufacturing Company, Ltd., Hsin-Chu (TW)

(72) Inventors: Shi-Sheng Hu, Tainan City (TW); Tsung-Hung Lee, Hsinchu City (TW); Chien-Tai Chan, Hsinchu City (TW)

(21) Appl. No.: 18/492,855

(22) Filed: Oct. 24, 2023

Related U.S. Application Data
(60) Provisional application No. 63/512,588, filed on Jul. 7, 2023.

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 21/823814; H01L 27/092; H01L 29/42392; H01L 29/66439; H01L 29/66545; H01L 29/775; H01L 29/78696

(57) ABSTRACT

A method for forming a semiconductor structure is provided. The method includes forming a fin structure over a substrate. The fin structure includes alternatingly stacked first semiconductor layers and second semiconductor layers. The method also includes laterally recessing the first semiconductor layers of the fin structure to form a plurality of notches, forming a plurality of inner spacers in the notches, laterally recessing the inner spacers to form a plurality of recesses in the inner spacers, and growing a source/drain feature over the fin structure. The recesses are sealed by the source/drain feature and the inner spacers to form a plurality of air spacers.

### PRIORITY

This application claims the benefit of U.S. Provisional Application No. 63/512,588, filed on Jul. 7, 2023 and entitled “SEMICONDUCTOR STRUCTURE WITH AIR SPACER AND METHOD FOR FORMING THE SAME,” which is incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A-1, 2A-2 and 2A-3 are cross-sectional views of a semiconductor structure corresponding to line X-X, line Y1-Y1 and line Y2-Y2 of FIG. 1, in accordance with some embodiments of the disclosure.

FIGS. 2B-1 and 2B-2 are cross-sectional views of a semiconductor structure corresponding to line X-X and line Y2-Y2 of FIG. 1, in accordance with some embodiments of the disclosure.

FIG. 2C-1 is a cross-sectional view of a semiconductor structure corresponding to line X-X of FIG. 1, in accordance with some embodiments of the disclosure.

FIG. 2D-1 is a cross-sectional view of a semiconductor structure corresponding to line X-X of FIG. 1, in accordance with some embodiments of the disclosure.

FIG. 2E-1 is a cross-sectional view of a semiconductor structure corresponding to line X-X of FIG. 1, in accordance with some embodiments of the disclosure.

FIG. 2F-1 is a cross-sectional view of a semiconductor structure corresponding to line X-X of FIG. 1, in accordance with some embodiments of the disclosure.

FIGS. 2G-1 and 2G-2 are cross-sectional views of a semiconductor structure corresponding to line X-X and line Y2-Y2 of FIG. 1, in accordance with some embodiments of the disclosure.

FIGS. 2H-1 and 2H-2 are cross-sectional views of a semiconductor structure corresponding to line X-X and line Y2-Y2 of FIG. 1, in accordance with some embodiments of the disclosure.

FIGS. 2I-1 and 2I-2 are cross-sectional views of a semiconductor structure corresponding to line X-X and line Y1-Y1 of FIG. 1, in accordance with some embodiments of the disclosure.

FIGS. 2J-1, 2J-2 and 2J-3 are cross-sectional views of a semiconductor structure corresponding to line X-X, line Y1-Y1 and line Y2-Y2 of FIG. 1, in accordance with some embodiments of the disclosure.

FIGS. 2A-4, 2B-3, 2C-2, 2D-2, 2E-2, 2F-2, 2G-3, 2H-3, 2I-3 and 2J-4 are plan views illustrating the formation of a semiconductor structure at various intermediate stages, in accordance with some embodiments of the disclosure.

FIG. 2G-4 is an enlarged view of FIG. 2G-1 to illustrate more detail of air spacers, in accordance with some embodiments of the disclosure.

FIGS. 3A, 3B, and 3C are cross-sectional views illustrating a cyclic deposition etch (CDE) epitaxy, in accordance with some embodiments of the disclosure.

FIG. 4A is a cross-sectional view of the semiconductor structure corresponding to line X-X of FIG. 1, in accordance with some embodiments of the disclosure.

FIG. 4B is a cross-sectional view of the semiconductor structure corresponding to line X-X of FIG. 1, in accordance with some embodiments of the disclosure.

FIG. 4B-1 is an enlarged view of FIG. 4B to illustrate more detail of air spacers, in accordance with some embodiments of the disclosure.

FIG. 4C is a modification of the cross-sectional view of FIG. 4B, in accordance with some embodiments of the disclosure.

FIG. 5 is a cross-sectional view of a semiconductor structure, in accordance with some embodiments of the disclosure.

FIG. 6 is a cross-sectional view of a semiconductor structure, in accordance with some embodiments of the disclosure.

FIG. 7 is a cross-sectional view of an air spacer and neighboring components, in accordance with some embodiments of the disclosure.

FIG. 8 is a cross-sectional view of an air spacer and neighboring components, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and the method for forming the semiconductor structure are provided. The semiconductor structure may include an inner spacer, a source/drain feature and an air spacer sealed by the inner spacer and the source/drain feature. The air spacer may reduce the parasitic capacitance between the gate stack and the source/drain feature, thereby enhancing the performance of the resulting semiconductor device.

In addition, by adjusting the parameters of the etching processes and/or etching steps for forming the inner spacer and the source/drain features, the air spacers may be formed with the dimensions that are positively related to the dimensions of the corresponding inner spacers. As a result, a better balance may be achieved between reducing the parasitic capacitance and avoiding breaking through the inner spacer. Therefore, the performance and the yield of the resulting semiconductors devices may improve.

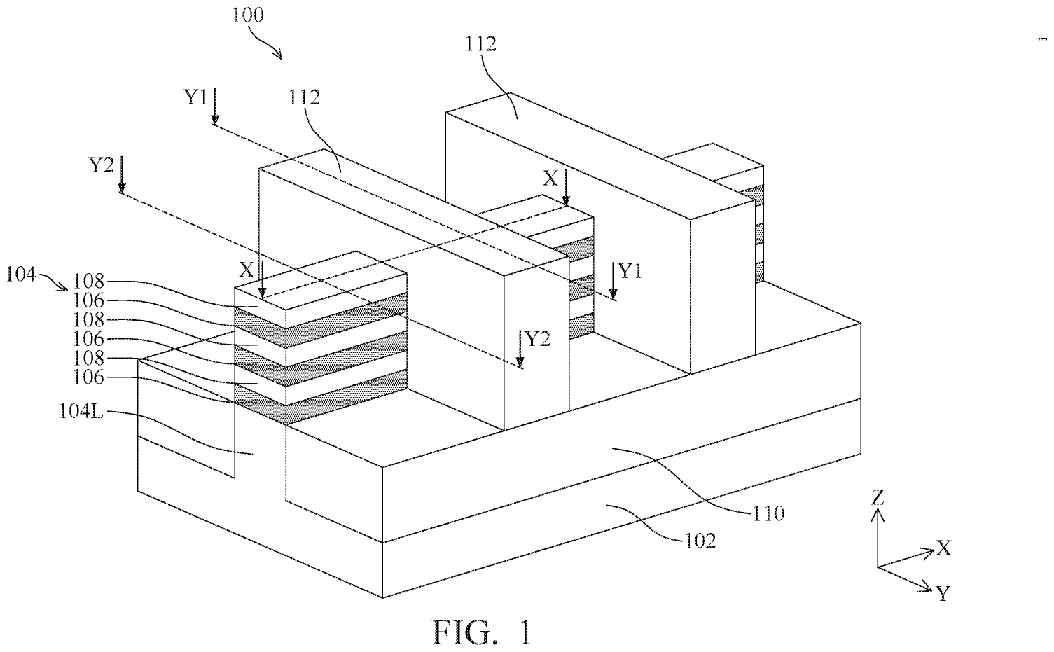

FIG. 1 is a perspective view of a semiconductor structure 100, in accordance with some embodiments. A semiconductor structure 100 is provided, as shown in FIG. 1, in accordance with some embodiments. The semiconductor structure 100 includes a substrate 102 and a fin structure 104 and an isolation structure 110 over the substrate 102, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 includes a lower fin element 104L surrounded by the isolation structure 110 and an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structure 104 extends in the X direction, in accordance with some embodiments. That is, the fin structure 104 has a longitudinal axis parallel to the X direction, in accordance with some embodiments. The X direction may also be referred to as the channel-extending direction. The current of the resulting semiconductor device (i.e., nanostructure transistor) flows in the X direction through the channel. The fin structure 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same.

Gate structures 112 are formed with longitudinal axes parallel to the Y direction and extending across and/or surrounding the channel regions of the fin structure 104, in accordance with some embodiments. The source/drain regions of the fin structure 104 are exposed from the gate structures 112, in accordance with some embodiments. The Y direction may also be referred to as a gate-extending direction, in accordance with some embodiments.

FIG. 1 further illustrates reference cross-sections that are used in later figures. Cross-section X-X is in a plan parallel to the longitudinal axis of the fin structure 104 (i.e., X direction) and through the fin structure 104. Cross-section Y1-Y1 is in a plan parallel to the longitudinal axis of the gate structure (i.e., Y direction) and across the channel region of the fin structure 104. Cross-section Y2-Y2 is in a plan parallel to the longitudinal axis of the gate structure (i.e., Y direction) and across the source/drain region of the fin structure 104.

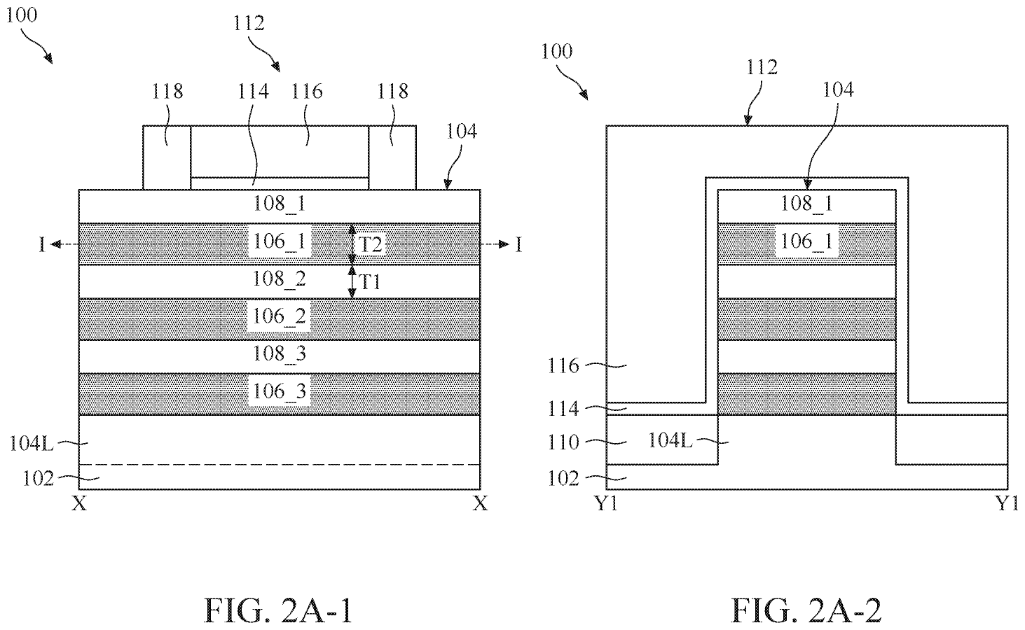

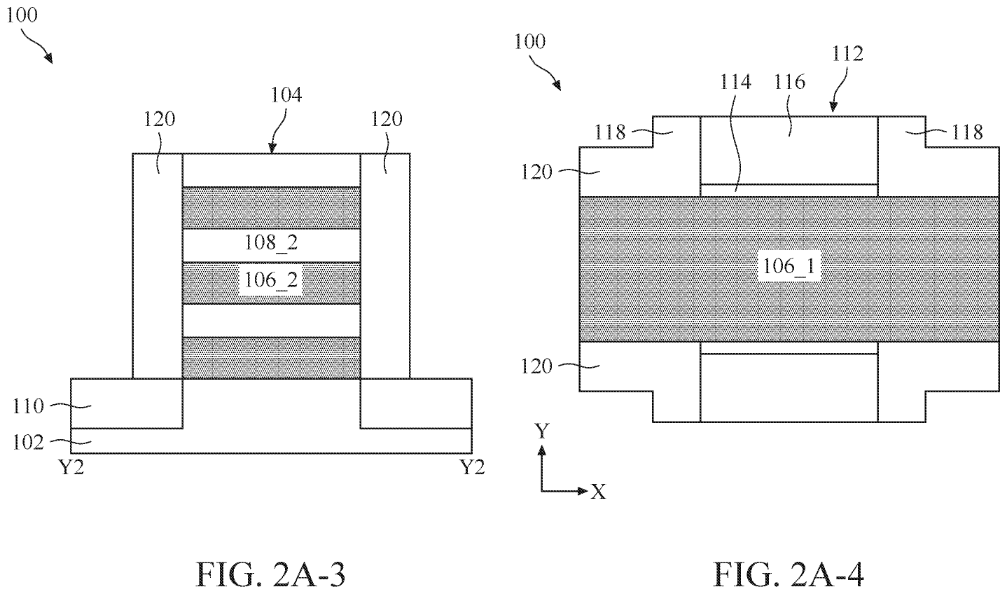

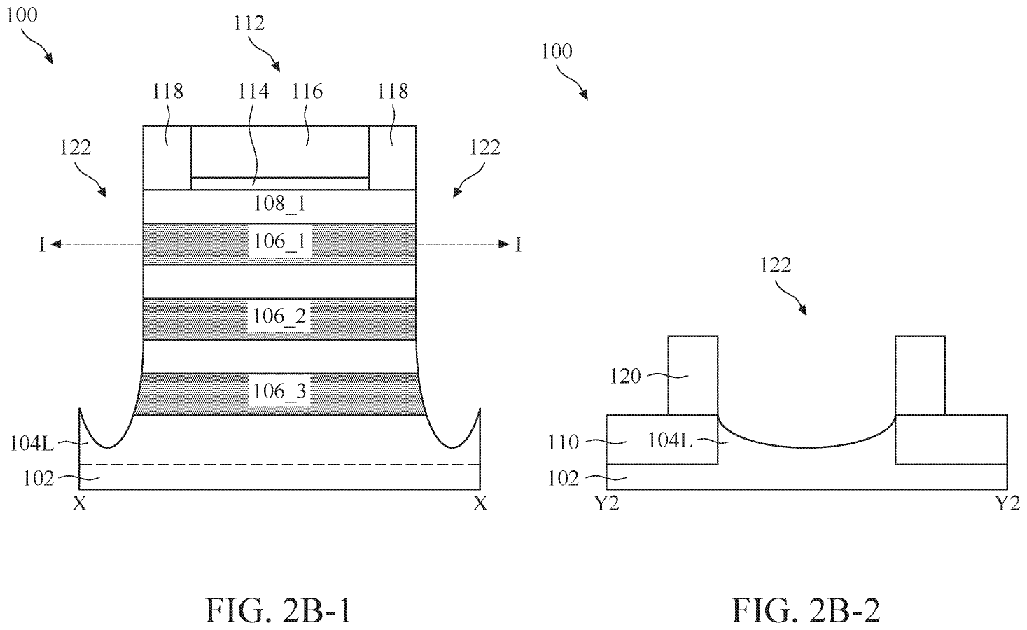

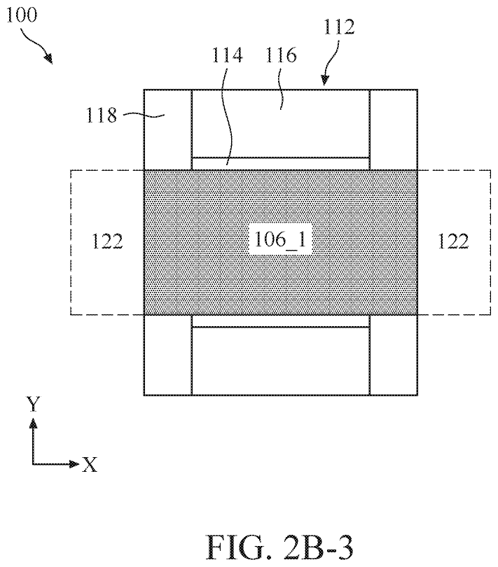

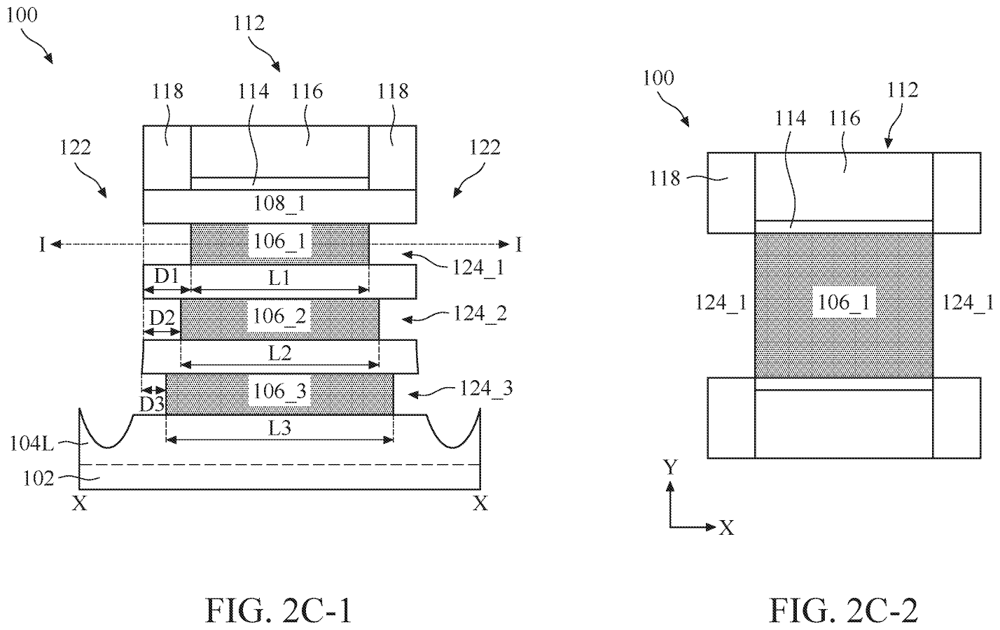

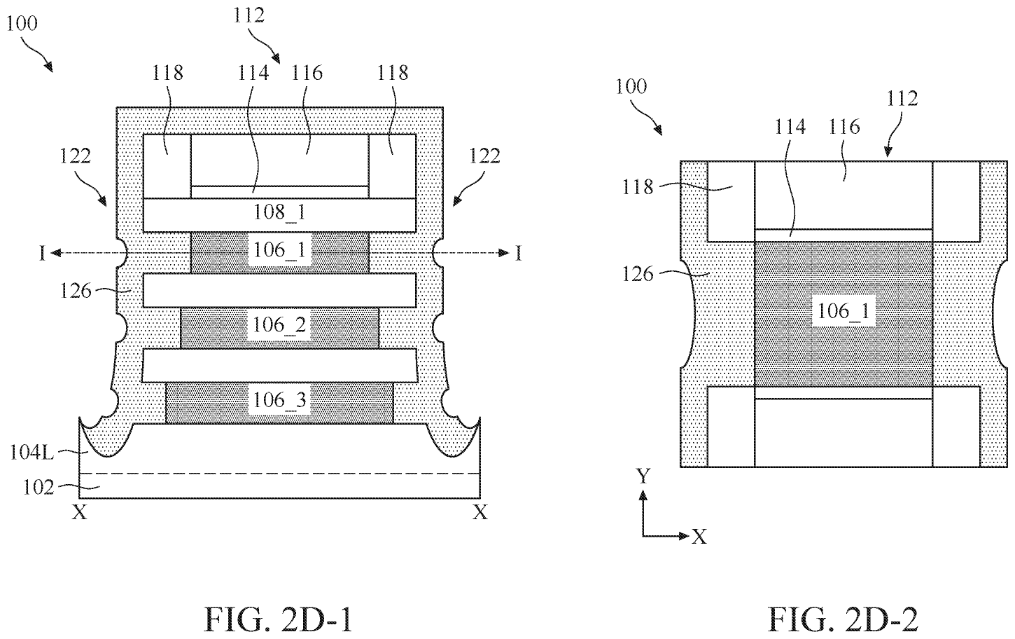

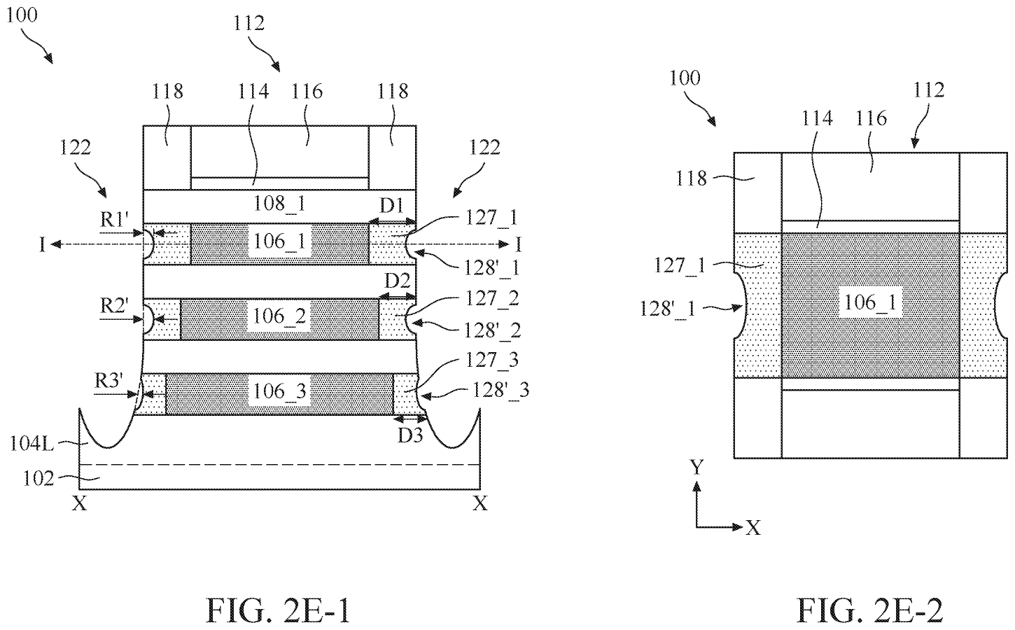

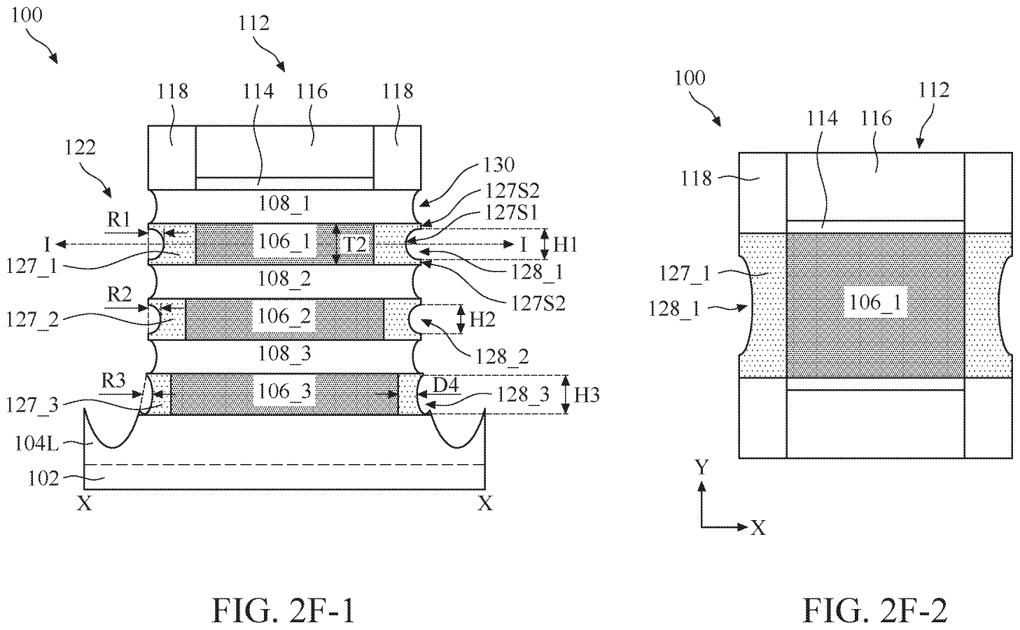

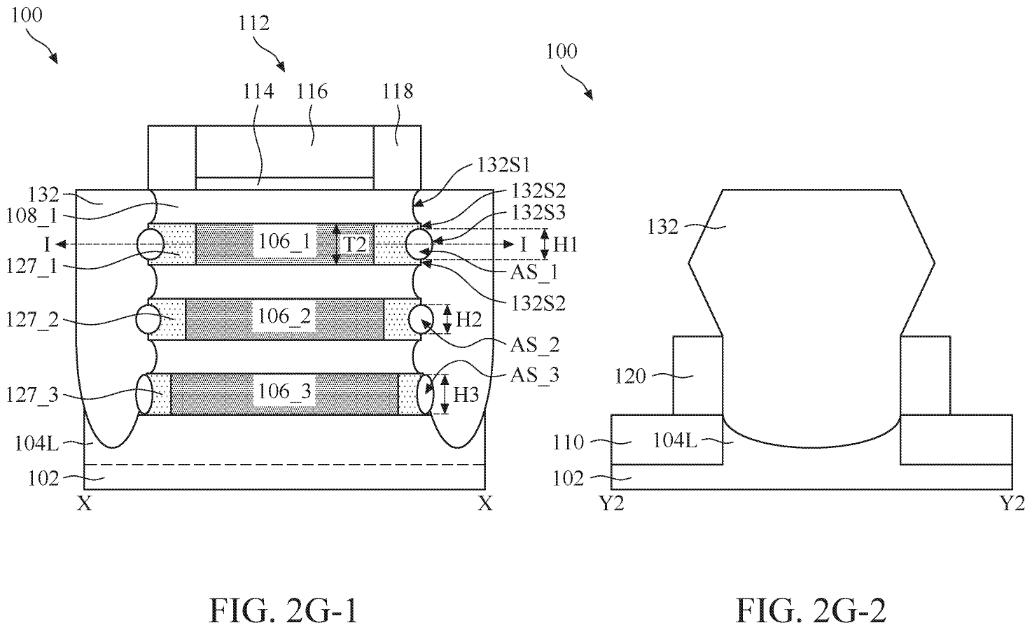

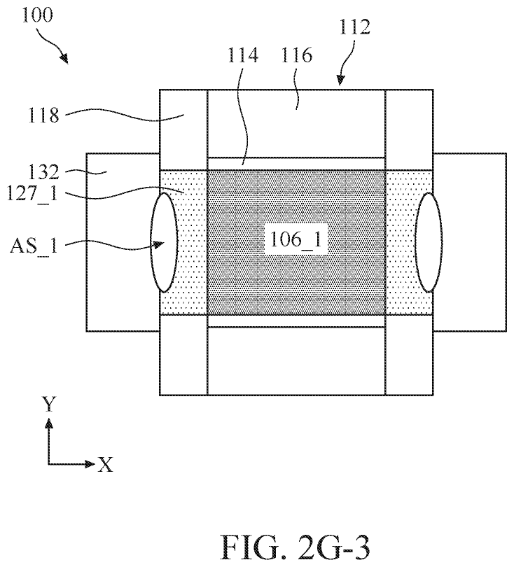

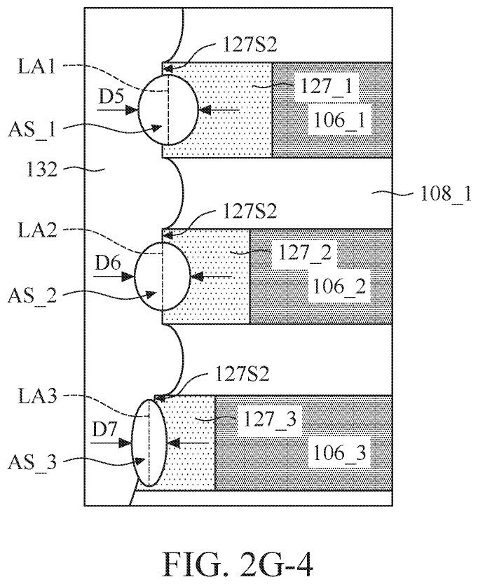

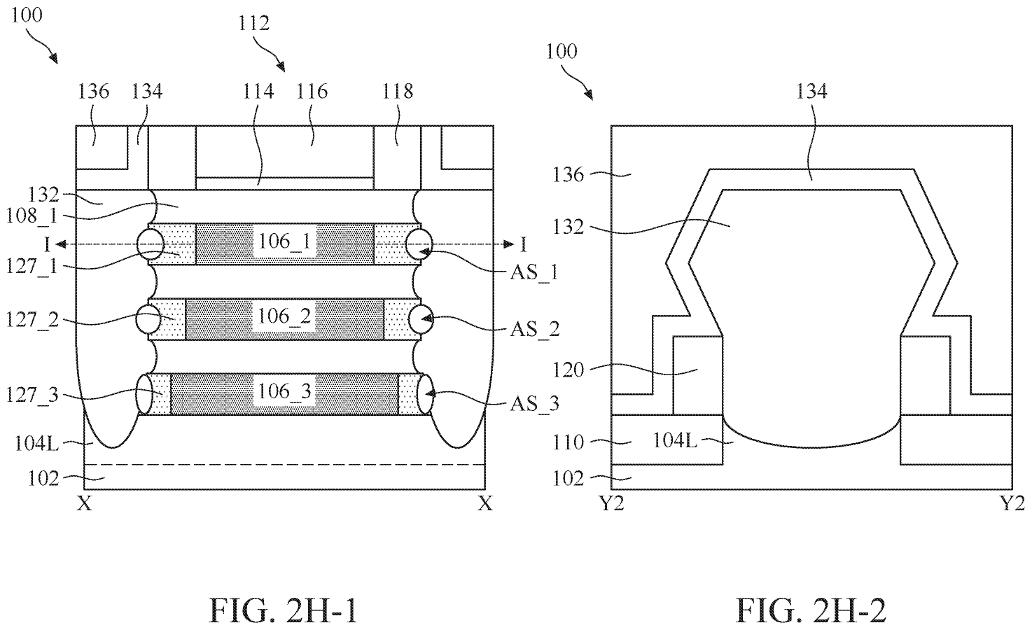

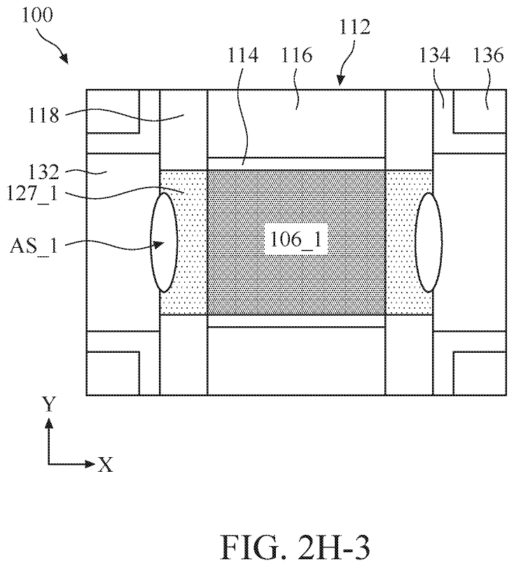

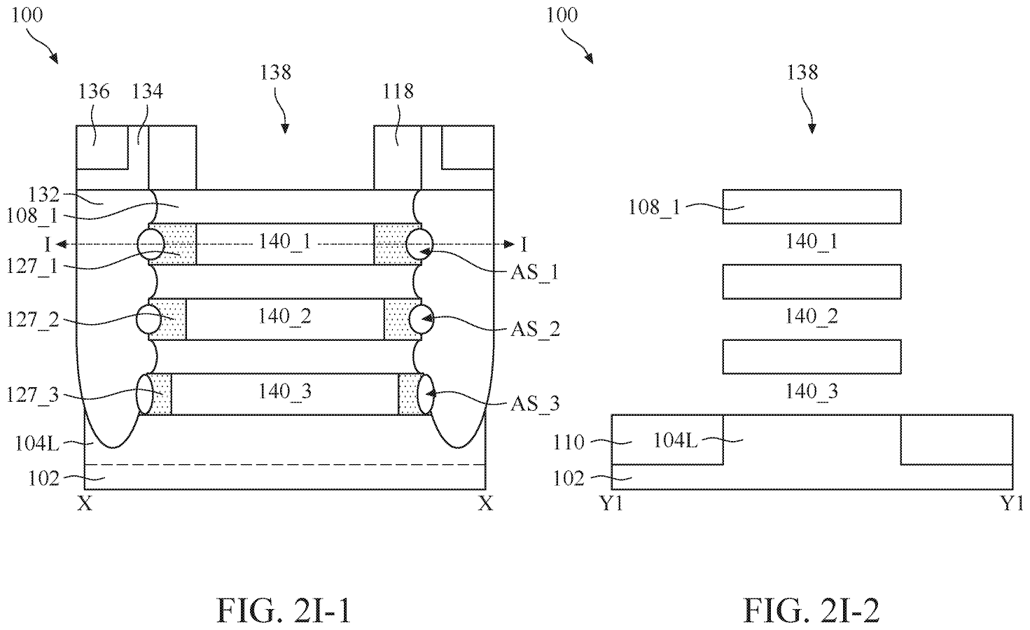

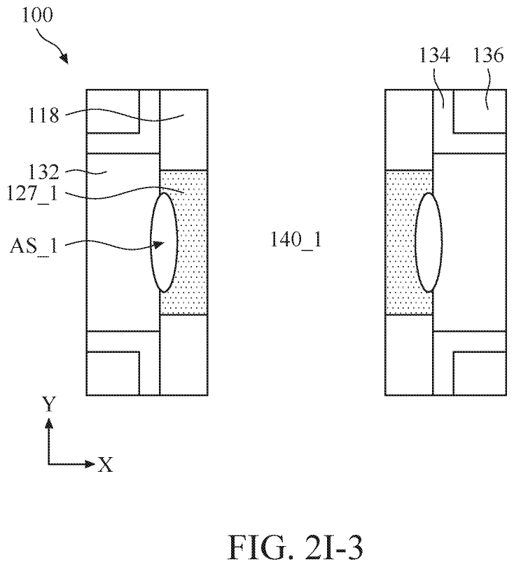

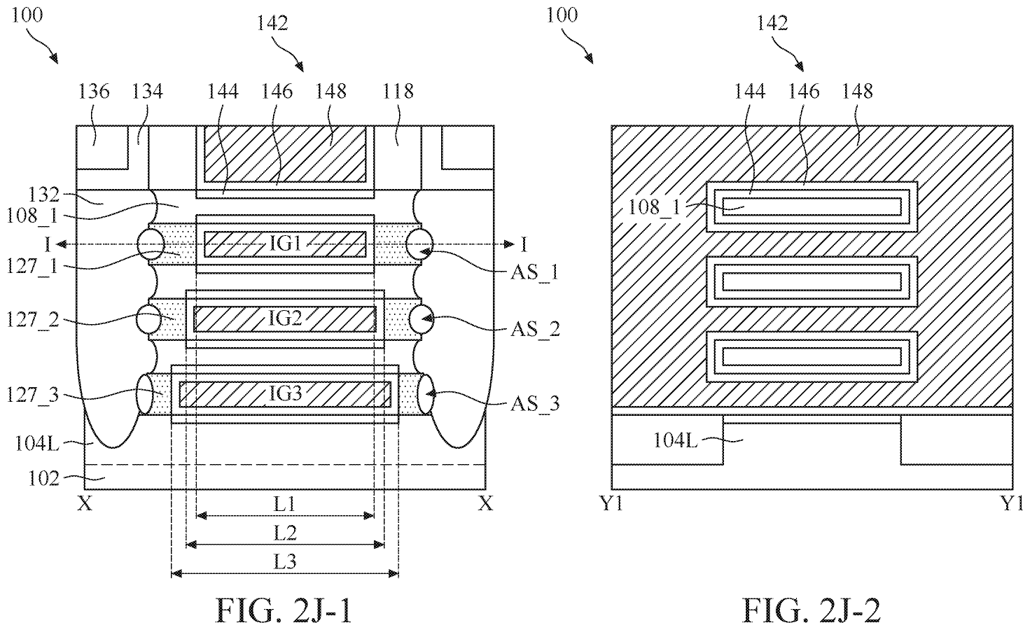

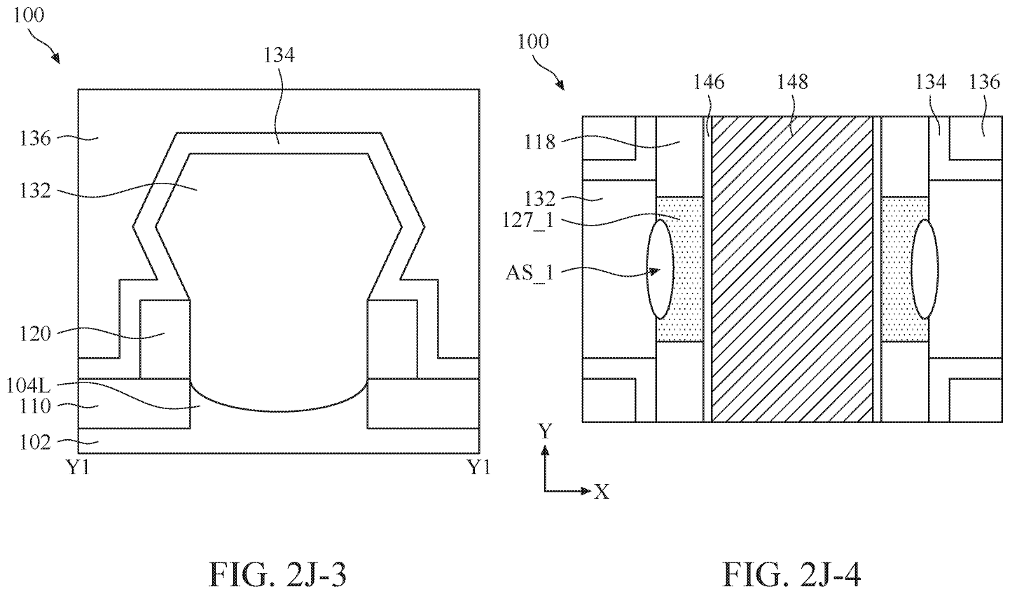

FIGS. 2A-1 through 2J-4 are schematic views illustrating the formation of a semiconductor structure 100 at various intermediate stages. FIGS. 2A-1, 2A-2 and 2A-3 are cross-sectional views of the semiconductor structure 100 after the formation of an active region 104, an isolation structure 110, a dummy gate structure 112, gate spacers 118, and fin spacers 120 corresponding to line X-X, line Y1-Y1 and line Y2-Y2 of FIG. 1. FIG. 2A-4 is a plan view illustrating the semiconductor structure 100 taken along plan I-I in FIG. 2A-1.

The semiconductor structure 100 includes a substrate 102 and an active region 104 over the substrate 102, as shown in FIGS. 2A-1 to 2A-4, in accordance with some embodiments. In some embodiments, the semiconductor structure 100 is used to form low-power devices with low leakage. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active region 104 extends in the X direction. The active region 104 has a longitudinal axis parallel to the X direction, in accordance with some embodiments. In some embodiments, the active region 104 is the fin structure 104 shown in FIG. 1. Although one active region 104 is shown in FIGS. 2A-1 to 2A-4, the number of active regions 104 is not limited thereto, and may depend on the performance and design demands of the resulting semiconductor device.

The formation of the active region 104 includes forming an epitaxial stack over the substrate 102 using an epitaxial growth process, in accordance with some embodiments. The epitaxial stack may be formed by depositing a first semiconductor layer 106 on the substrate 102, depositing a second semiconductor layer 108 on the first semiconductor layer 106, and repeating the cycle of depositing the semiconductor layers 106 and 108 several times. The first semiconductor layers 106 and the second semiconductor layers 108 are alternately stacked, in accordance with some embodiments. The epitaxial growth process may be molecular beam epitaxy (MBE), metal organic chemical vapor deposition (MOCVD), vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments. Although three first semiconductor layers 106 and three second semiconductor layers 108 are shown in FIGS. 2A-1 to 2A-3, the number is not limited to three, and can be two or four, and is less than ten.

In some embodiments, the thickness T1 of the second semiconductor layers 108 is in a range from about 3 nm to about 20 nm, such as about 4 nm to about 12 nm. In some embodiments, the thickness T2 of each of the first semiconductor layers 106 is in a range from about 2 nm to about 20 nm, such as about 2 nm to about 10 nm. In some embodiments, the first semiconductor layers are denoted as 106_1, 106_2 and 106_3 from top to bottom, and the second semiconductor layers are denoted as 108_1, 108_2 and 108_3 are denoted as 108_1, 108_2 and 108_3 from top to bottom.

The formation of the active region 104 further includes patterning the epitaxial stack and the underlying substrate 102 using photolithography and etching processes, thereby forming trenches and the active region 104 protruding from between trenches, in accordance with some embodiments. The portion of the substrate 102 protruding from between the trenches serves as the lower fin element 104L of the active region 104, in accordance with some embodiments. The remainder of the epitaxial stack (including the first semiconductor layers 106 and the second semiconductor layers 108) serves as the upper fin element of the active region 104, in accordance with some embodiments.

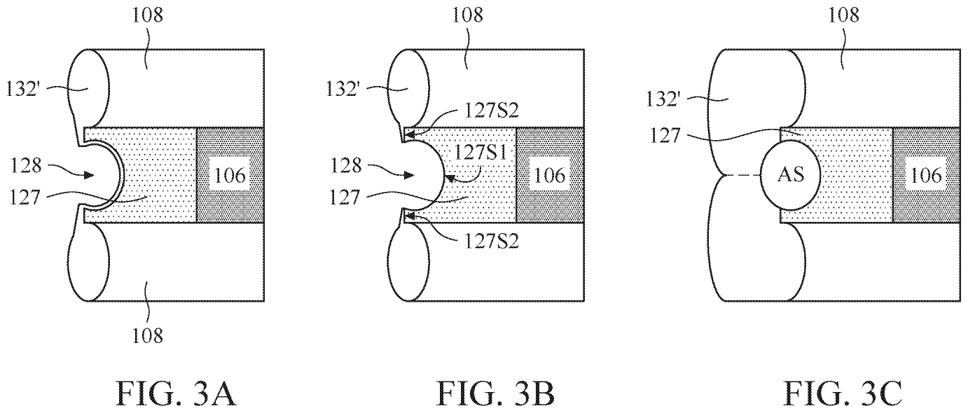

An isolation structure 110 is formed to surround the lower fin element 104L of the active region 104, as shown in FIGS. 2A-2 and 2A-3, in accordance with some embodiments. The isolation structure 110 is configured to electrically isolate neighboring active regions 104 and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) to expose the sidewalls of the upper fin element of the active region 104, in accordance with some embodiments. The remaining insulating material serves as the isolation structure 110, in accordance with some embodiments.

A dummy gate structure 112 is formed across the active region 104 and the isolation structure 110, as shown in FIGS. 2A-1, 2A-2 and 2A-4, in accordance with some embodiments. The dummy gate structure 112 is configured as a sacrificial structure and will be replaced with the final gate stack, in accordance with some embodiments. In some embodiments, the dummy gate structure 112 extends in the Y direction. That is, the dummy gate structure 112 has a longitudinal axis parallel to the Y direction, in accordance with some embodiments. The dummy gate structure 112 surrounds the channel region of the active region 104, in accordance with some embodiments. The dummy gate structure 112 may be the gate structure 112 shown in FIG. 1. Although one dummy gate structure 112 is shown in FIGS. 2A-1 to 2A-4, the number of dummy gate structures 112 is not limited thereto, and may depend on the performance and design demands of the resulting semiconductor device.

The dummy gate structure 112 includes a dummy gate dielectric layer 114 and a dummy gate electrode layer 116 formed over the dummy gate dielectric layer 114, as shown in FIGS. 2A-1, 2A-2 and 2A-4, in accordance with some embodiments. In some embodiments, the dummy gate dielectric layer 114 is conformally formed along the upper fin element of the active region 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structure 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structure 112.

The patterning process includes forming a patterned hard mask layer (not shown) over the material for the dummy gate electrode layer 116, in accordance with some embodiments. The patterned hard mask layer corresponds to and overlaps the channel region of the active region 104, in accordance with some embodiments. The materials for the dummy gate dielectric layer 114 and the dummy gate electrode layer 116, uncovered by the patterned hard mask layer, are etched away until the active region 104 and the top surface of the isolation structure 110 are exposed, in accordance with some embodiments.

Gate spacers 118 are formed along opposite sidewalls of the dummy gate structure 112, and fin spacers 120 are formed along opposite sidewalls of the active region 104, as shown in FIGS. 2A-1, 2A-3 and 2A-4, in accordance with some embodiments. The gate spacers 118 extend in the Y direction and across the active region 104 and the isolation structure 110, in accordance with some embodiments. The gate spacers 118 are used to offset the subsequently formed source/drain features and separate the source/drain features from the gate structure, in accordance with some embodiments.

The fin spacers 120 extend in the X direction, in accordance with some embodiments. The fin spacers 120 may be used to confine the growth of epitaxial material to prevent neighboring epitaxial material from merging with each other, in accordance with some embodiments.

In some embodiments, the gate spacers 118 and the fin spacers 120 are formed from a continuous dielectric material. In some embodiments, the formation of the gate spacers 118 and the fin spacers 120 includes globally and conformally depositing a dielectric material over the semiconductor structure 100 using ALD, CVD (such as LPCVD, PECVD, HDP-CVD and HARP), another suitable method, and/or a combination thereof, followed by an anisotropic etching process. In some embodiments, the etching process is performed without an additional photolithography process. In some embodiments, the dielectric material for the gate spacers 118 and the fin spacers 120 may be silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof.

The vertical portions of the dielectric material left remaining on the opposite sides of the dummy gate structure 112 serve as the gate spacers 118, in accordance with some embodiments. The vertical portions of the dielectric material left remaining on the opposite sides of the active region 104 serve as fin spacers 120, in accordance with some embodiments.

FIGS. 2B-1 and 2B-2 are cross-sectional views of the semiconductor structure 100 after an etching process corresponding to line X-X and line Y2-Y2 of FIG. 1, in accordance with some embodiments of the disclosure. FIG. 2B-3 is a plan view of the semiconductor structure 100 taken along plan I-I in FIG. 2B-1.

An etching process is performed to recess the source/drain regions of the active region 104, thereby forming source/drain recesses 122, as shown in FIGS. 2B-1 to 2B-3, in accordance with some embodiments. The etching process may be an anisotropic etching process such as dry plasma etching, an isotropic etching process such as dry chemical etching, remote plasma etching or wet chemical etching, and/or a combination thereof. The gate spacers 118 and the dummy gate structure 112 may serve as etch masks such that the source/drain recesses 122 are formed self-aligned on opposite sides of the dummy gate structure 112, in accordance with some embodiments. The bottom of the source/drain recess 122 extends into the lower fin element 104L, in accordance with some embodiments. The fin spacers 120 are also recessed in the etching process, in accordance with some embodiments.

FIG. 2C-1 is a cross-sectional view of the semiconductor structure 100 after an etching process corresponding to line X-X of FIG. 1, in accordance with some embodiments of the disclosure. FIG. 2C-2 is a plan view of the semiconductor structure 100 taken along plan I-I in FIG. 2C-1.

An etching process is performed to laterally recess, from the source/drain recesses 122 toward the channel region, the first semiconductor layers 106 of the fin structure 104 to form notches 124, as shown in FIGS. 2C-1 and 2C-2, in accordance with some embodiments. In some embodiments, the etching process is an isotropic etching such as dry chemical etching, remote plasma etching, wet chemical etching, another suitable technique, or a combination thereof.

The notches 124 are formed between adjacent second semiconductor layers 108 and between the lowermost second semiconductor layer 108 and the lower fin element 104L, in accordance with some embodiments. In some embodiments, the notches 124 are located directly below the gate spacers 120. In some embodiments, the notches 124 are denoted as 124_1, 124_2 and 124_3 from top to bottom, which are formed in the first semiconductor layers 106_1, 106_2 and 106_3, respectively.

In some embodiments, in the X direction, the width D1 (or recessing depth) of the notch 124_1 is greater than the width D2 (or recessing depth) of the notch 1242, and the width D2 (or recessing depth) is greater than the width D3 (or recessing depth) of the notch 124_3. That is, the dimensions of the notches 124 in the X direction decrease as the level of the first semiconductor layers 106 decreases from top to bottom, in accordance with some embodiments.

The dimension variation of the notches 124 at different positions can be adjusted by adjusting the parameters (e.g., source/bias RF power, gas flow rate, pressure, etc.) of the etching process. In some other embodiments, the dimensions of the notches 124 in the X direction may increase as the level of the notch 124 decreases from top to bottom.

In some embodiments, in the X direction, the length L1 of the first semiconductor layer 106_1 is less than the length L2 of the first semiconductor layer 1062, and the length L2 is less than the length L3 of the first semiconductor layer 106_3. That is, the dimensions of the first semiconductor layers 106_1 in the X direction increase as the level of the first semiconductor layer 106 decreases from top to bottom, in accordance with some embodiments.

Although the recessed sidewalls of the first semiconductor layers 106 are illustrated as substantially flat, the recessed sidewalls of the first semiconductor layers 106 may be curved, e.g., concave.

FIG. 2D-1 is a cross-sectional view of the semiconductor structure 100 after the formation of a dielectric material 126 corresponding to line X-X of FIG. 1, in accordance with some embodiments of the disclosure. FIG. 2D-2 is a plan view of the semiconductor structure 100 taken along plan I-I in FIG. 2D-1.

A dielectric material 126 is globally deposited over the semiconductor structure 100, as shown in FIGS. 2D-1 and 2D-2, in accordance with some embodiments. In some embodiments, the dielectric material 126 is silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the deposition process includes ALD, CVD (such as PECVD, LPCVD or HARP), another suitable technique, or a combination thereof.

The dielectric material 126 is deposited to overfill the notches 124, in accordance with some embodiments. In some embodiments, portions of the surface of the dielectric material 126 corresponding to the notches 124 may have curved profiles (e.g., concave). In some other embodiments, the portions of the surface of the dielectric material 126 corresponding to the notches 124 may be substantially flat.

FIG. 2E-1 is a cross-sectional view of the semiconductor structure 100 after an etching process corresponding to line X-X of FIG. 1, in accordance with some embodiments of the disclosure. FIG. 2E-2 is a plan view of the semiconductor structure 100 taken along plan I-I in FIG. 2E-1.

An etching process is performed on the dielectric material 126 to remove portions of the dielectric material 126 outside the notches 124, in accordance with some embodiments. In some embodiments, the etching process includes an anisotropic etching process such as dry plasma etching, an isotropic etching process such as dry chemical etching, remote plasma etching or wet chemical etching, or a combination thereof. Remaining portions of the dielectric material 126 in the notches 124 form inner spacers 127, as shown in FIGS. 2E-1 and 2E-2, in accordance with some embodiments.

The inner spacers 127 abut the recessed sidewalls of the first semiconductor layers 106, and are located between adjacent second semiconductor layers 108 and between the lowermost second semiconductor layer 108 and the lower fin element 104L, in accordance with some embodiments. The inner spacers 127 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacers 127 are denoted as 127_1, 127_2 and 127_3 from top to bottom, which are formed adjacent to the first semiconductor layers 106_1, 106_2 and 106_3, respectively. The maximum width of the inner spacers 127 may be substantially the same as the width (e.g., D1, D2 and D3) of the notches 124, in accordance with some embodiments. In some embodiments, in the X direction, the maximum width D1 of the inner spacer 127_1 is greater than the maximum width D2 of the inner spacer 127_2, and the maximum width D2 is greater than the maximum width D3 of the inner spacer 127_3. That is, the maximum widths of the inner spacers 127 decrease as the level of the inner spacer 127 decreases from top to bottom, in accordance with some embodiments.

Due to the characteristics of the etching process, the exposed surfaces of the inner spacers 127 are recessed thereby forming recesses 128′, in accordance with some embodiments. As a result, the exposed surfaces of the inner spacers 127 have concave profiles, in accordance with some embodiments. In some embodiments, the recesses 128′ are denoted as 128′_1, 128′_2 and 128′_3 from top to bottom, which are formed in the inner spacers 127_1, 127_2 and 127_3, respectively.

In some embodiments, in the X direction, the width R1′ (or recessing depth) of the recess 128′_1 is greater than the width R2′ (or recessing depth) of the recess 128′_2, and the width R2′ (or recessing depth) is greater than the width R3′ (or recessing depth) of the recess 128′_3. That is, the dimensions of the recesses 128′ in the X direction decrease as the level of the recess 128′ decreases from top to bottom, in accordance with some embodiments.

FIG. 2F-1 is a cross-sectional view of the semiconductor structure 100 after an etching process corresponding to line X-X of FIG. 1, in accordance with some embodiments of the disclosure. FIG. 2F-2 is a plan view of the semiconductor structure 100 taken along plan I-I in FIG. 2F-1.

An etching process is performed on the semiconductor structure 100 to laterally recess, from the source/drain recesses 122, the second semiconductor layers 108, thereby forming recesses 130, as shown in FIG. 2F-1, in accordance with some embodiments. In some embodiments, the etching process is an isotropic etching such as dry chemical etching, remote plasma etching, wet chemical etching, another suitable technique, or a combination thereof. The lateral recessing of the second semiconductor layers 108 may reduce junction overlap, which may improve the performance of the resulting semiconductor devices, in accordance with some embodiments.

The recessed second semiconductor layers 108 have concave surfaces that are exposed from the recesses 130, in accordance with some embodiments. In the etching process, the inner spacers 127 are also recessed, thereby enlarging the recesses 128′, as shown in FIGS. 2F-1 and 2F-2, in accordance with some embodiments. The enlarged recesses 128′ are denoted as 128. In some embodiments, the recesses 128 are denoted as 128_1, 128_2 and 128_3 from top to bottom.

In some embodiments, in the X direction, the width R1 (or recessing depth) of the recess 128_1 is greater than the width R2 of (or recessing depth) the recess 128_2, and the width R2 (or recessing depth) is greater than the width R3 (or recessing depth) of the recess 128_3. That is, the dimensions of the recesses 128 in the X direction decrease as the level of the recess 128 decreases from top to bottom, in accordance with some embodiments. Such a dimension variation of the recesses 128 at different positions can be adjusted by adjusting the parameters (e.g., source/bias RF power, gas flow rate, pressure, etc.) of the etching process. In addition, the widths of the recesses 130 (dimensions in the X direction) is less than the widths (e.g., R1) of the recesses 128. In some other embodiments, the widths of the recesses 130 may be greater than the dimensions (e.g., R1) of the recesses 128.

In some embodiments, the recess 128_1 has a height H1, the recess 128_2 has a height H2, and the recess 128_3 has a height H3. In some embodiments, the heights H1, H2 and H3 are equal to or less than the thickness T2 of the first semiconductor layer 106. In some embodiments, the heights H1, H2 and H3 are the same. In some other embodiments, the heights H1, H2 and H3 are different (e.g., H1>H2>H3; H1>H3>H2; H2>H1>H3; H2>H3>H1; H3>H1>H2 or H3>H2>H1). In some embodiments, the heights H1, H2 and H3 are in a range from about 0.67 nm to about 10 nm. In some embodiments, the ratio (H1/T2, H2/T2 or H3/T2) of the height H1, H2 or H3 to the thickness T2 is in a range from about 0.33 to about 1.0. In some embodiments, the ratio (H1/T2, H2/T2 or H3/T2) is equal to 1. If the ratio is too small (e.g., H1/T2<0.33), the volume of subsequently formed air spacers may be too small, so that the parasitic capacitance between the gate stack and the source/drain features may be not sufficiently reduced.

After the etching process, each of the inner spacers 127 has a minimum width (i.e., the minimum dimension in the X direction) at its middle height. In some embodiments, the minimum widths of the inner spacers 127_1, 127_2 and 127_3 may be different. For example, the minimum widths of the inner spacers 127 decrease as the level of the inner spacer 127 decreases from top to bottom. In some embodiments, the bottommost inner spacer 127_3 has a minimum width D4, which is equal to or greater than about 3 nm. If the minimum widths of the inner spacers 127 are too narrow (e.g., less than about 3 nm), the inner spacer may be broken in the subsequent channel-release process. In some other embodiments, the inner spacers 127 have the same minimum widths.

In some embodiments where the height H1 of the recess 128 is less than the thickness T2 of the first semiconductor layer 106, the exposed sidewall of the inner spacer 127 facing the source/drain region has a recessed surface 127S1 and two unrecessed surfaces 127S2, as shown in FIG. 2F-1. The recessed surface 127S1 is connected between the two unrecessed surfaces 127S2, in accordance with some embodiments. The recessed surface 127S1 is curved (e.g., concave), in accordance with some embodiments. The unrecessed surfaces 127S2 are substantially flat and extend vertically, in accordance with some embodiments.

FIGS. 2G-1 and 2G-2 are cross-sectional views of the semiconductor structure 100 after the formation of source/drain features 132 corresponding to line X-X and line Y2-Y2 of FIG. 1, in accordance with some embodiments of the disclosure. FIG. 2G-3 is a plan view of the semiconductor structure 100 taken along plan I-I in FIG. 2G-1.

The source/drain features 132 are grown from the exposed side surfaces of the second semiconductor layers 108 and the lower fin element 104L in the source/drain recesses 122 using an epitaxial growth process, as shown in FIGS. 2G-1 to 2G-3, in accordance with some embodiments. The epitaxial growth process may be molecular beam epitaxy (MBE), metal organic chemical vapor deposition (MOCVD), or vapor phase epitaxy (VPE), or another suitable technique.

The growth of the source/drain features 132 is initially confined by the fin spacers 120 such that the source/drain features 132 have a narrow body portion between the fin spacers 120, in accordance with some embodiments. Once the source/drain features 132 grow to protrude from the fin spacers 120, the source/drain features 132 may grow to have facet surfaces that have specific crystalline orientations such that the source/drain features 132 has a wider head portion. Although the source/drain features 132 are illustrated as having facet surfaces, the surface of the source/drain features 132 may have curved in some other embodiments.

In some embodiments, the source/drain features 132 are made of any suitable semiconductor material for n-type semiconductor devices or p-type semiconductor devices. In some embodiments, the source/drain features 132 are doped. The concentration of the dopant in the source/drain features 132 in a range from about 1×10¹⁹ cm⁻³ to about 6×10²¹ cm⁻³. An annealing process may be performed on the semiconductor structure 100 to activate the dopants in the source/drain features 132, in accordance with some embodiments.

In some embodiments wherein the active region 104 is to be formed as an N-type nanostructure device (such as n-channel GAA FET), the source/drain features 132 are made of semiconductor material such as SiP, SiAs, SiCP, SiC, Si, GaAs, another suitable semiconductor material, or a combination thereof. In some embodiments, the source/drain features 132 are doped with the n-type dopant during the epitaxial growth process. For example, the n-type dopant may be phosphorous (P) or arsenic (As). For example, the source/drain features 132 may be the epitaxially grown Si doped with phosphorous to form silicon:phosphor (Si:P) source/drain features and/or arsenic to form silicon:arsenic (Si:As) source/drain feature.

In some embodiments wherein the active region 104 is to be formed as a P-type nanostructure device (such as p-channel GAA FET), the source/drain features 132 are made of semiconductor material such as SiGe, Si, GaAs, another suitable semiconductor material, or a combination thereof. In some embodiments, the source/drain features 132 are doped with the p-type dopant during the epitaxial growth process. For example, the p-type dopant may be boron (B) or BF₂. For example, the source/drain features 132 may be the epitaxially grown SiGe doped with boron (B) to form silicon germanium:boron (SiGe:B) source/drain feature.

In some embodiments, the epitaxial growth process for forming the source/drain 132 is a cyclic deposition etch (CDE) epitaxy. For example, CDE includes periodic steps, in which the semiconductor structure 100 is exposed to a pulse of precursors for deposition and doping and an etchant gas for a first period of time, followed by a second period of time wherein the semiconductor structure 100 is exposed to the etchant gas without the precursors, followed by a third period of time wherein the semiconductor structure 100 is again exposed to the pulse of the precursors for deposition and doping and an etchant gas, and so on, until a desired epitaxial layer thickness is achieved.

FIGS. 3A-3C are cross-sectional views illustrating the cyclic deposition etch (CDE) epitaxy for growing the epitaxial material of the source/drain feature 132, in accordance with some embodiments of the disclosure.

The semiconductor structure 100 is placed in a processing chamber and a cyclic deposition etch epitaxy is performed in the processing chamber, in accordance with some embodiments. FIG. 3A illustrates a deposition step of the cyclic deposition etch epitaxy, wherein an epitaxial material 132′ is deposited, in accordance with some embodiments.

The semiconductor structure 100 is exposed to a continuous flow of a precursor for deposition (e.g., silicon-containing precursor such as SiH₄ and/or dichlorosilane (DCS) gas), a precursor for doping (e.g., PH₃, PF₃, and/or PF₅ for n-type; or BF₃, B₂H₆, and/or BCl₃ for p-type) and an etchant gas (e.g., Cl₂ or HCl), in accordance with some embodiments. The etchant gas may be configured to continuously and selectively remove amorphous portions of the epitaxial material 132′ from the substrate.

In some embodiments, in the deposition step, the epitaxial material 132′ is deposited on the exposed surfaces of the second semiconductor layers 108 and the exposed surface of the inner spacer 127. The inner spacer 127 and the second semiconductor layer 108 provide surfaces with different types of bonding for the epitaxial material 132′. For example, the dielectric surface of the inner spacer 127 may provide a nitrogen dangling bond, and the growth rate (or thickness) of the epitaxial material 132′ on the exposed surfaces of the second semiconductor layers 108 is much greater than the growth rate (or thickness) of the epitaxial material 132′ on the exposed surface of the inner spacer 127, in accordance with some embodiments. After a deposition step of the cyclic deposition etch epitaxy, the recess 128 is partially filled with the epitaxial material 132′, in accordance with some embodiments.

FIG. 3B illustrates an etching step of the cyclic deposition etch epitaxy after the deposition step of FIG. 3A, wherein the source of the precursors for deposition and doping have been turned off to allow the continuous flow of etchant gas to selectively etch the epitaxial material 132′.

In the etching step, the epitaxial material 132′ is etched, and the epitaxial material 132′ deposited on recessed surface 127S1 of the inner spacer 127 is removed, as shown in FIG. 3B, in accordance with some embodiments. The epitaxial material 132′ is removed from the recess 128, and the recessed surface 127S1 is exposed again, in accordance with some embodiments. In some embodiments, the epitaxial material 132′ deposited on the unrecessed surfaces 127S2 of the inner spacer 127 remains after the etching step. In some other embodiments, the epitaxial material 132′ deposited on the unrecessed surfaces 127S2 of the inner spacer 127 may be also removed to expose the surfaces 127S2.

FIG. 3C illustrates the epitaxial material 132′ after several cycles of the deposition and the etching steps shown in FIGS. 3A-3B. The cycle of the deposition and the etching may repeat several times, so that the epitaxial material 132′ formed on the neighboring second semiconductor layers 108 merges with each other. Because the epitaxial material 132′ is removed from the recess 128 in the etching step of each cycle, the recess 128 remains unfilled throughout the cyclic deposition etch epitaxy, and is sealed by the epitaxial material 132′ and the inner spacer 127 thereby forming an air spacer AS, as shown in FIG. 3C, in accordance with some embodiments. The number of cycles of the cyclic deposition etch epitaxy may depend on the desired thickness of the source/drain feature 132.

Referring back to FIG. 2G-1, the sidewall of the source/drain feature 132 facing the channel region includes first surfaces 132S1, second surfaces 132S2 and third surfaces 132S3, in accordance with some embodiments. The first surfaces 132S1 are convex, and are interfaced and mated with the concave surfaces of the recessed second semiconductor layers 108, in accordance with some embodiments. The second surfaces 132S2 are substantially flat, and are interfaced with the unrecessed surfaces 127S2 of the inner spacers 127, in accordance with some embodiments. The third surfaces 132S3 corresponds to (or faces) the recessed surfaces 127S1 of the inner spacer 127 and are concave, in accordance with some embodiments.

Each of the air spacer AS is defined by the third surface 132S3 of the source/drain feature 132 and the recessed surface 127S1 of the inner spacer 127, in accordance with some embodiments. In some embodiments, the air spacers AS have a lower K-value than the inner spacers 127, and may further reduce the parasitic capacitance between the gate stack and the source/drain features 132, in accordance with some embodiments.

In some embodiments, the air spacer AS_1 has a height H1, the air spacer AS_2 has a height H2, and the air spacer AS_3 has a height H3. In some embodiments, the heights H1, H2 and H3 are equal to or less than the thickness T2 of the first semiconductor layer 106. In some embodiments, the heights H1, H2 and H3 are the same. In some other embodiments, the heights H1, H2 and H3 are different (e.g., H1>H2>H3; H1>H3>H2; H2>H1>H3; H2>H3>H1; H3>H1>H2 or H3>H2>H1). the air spacers AS may also have the height H1 that is equal to or less than the thickness T2 of the first semiconductor layer 106. In some embodiments, the height H1 is in a range from about 0.67 nm to about 10 nm. In some embodiments, the ratio (H1/T2, H2/T2 or H3/T2) of the height H1, H2 or H3 to the thickness T2 is in a range from about 0.33 to about 1.0. In some embodiments, the ratio (H1/T2, H2/T2 or H3/T2) is equal to 1. If the ratio is too small (e.g., H1/T2<0.33), the volume of subsequently formed air spacers may be too small, so that the parasitic capacitance between the gate stack and the source/drain features may be not sufficiently reduced.

FIG. 2G-4 is an enlarged view of FIG. 2G-1 to illustrate more detail of the air spacers AS, in accordance with some embodiments of the disclosure. In some embodiments, the air spacers AS are denoted AS_1, AS_2 and AS_3 from top to bottom, which correspond to the inner spacers 127_1, 127_2 and 127_3, respectively.

In some embodiments, in the X direction, the dimension D5 of the air spacer AS_1 is greater than the dimension D6 of the air spacer AS_2, and the dimension D6 is greater than the dimension D7 of the air spacer AS_3. That is, the dimensions of the air spacers AS in the X direction decrease as the level of the air spacer AS decreases from top to bottom, in accordance with some embodiments.

In accordance with the embodiments of the present disclosure, by adjusting the parameters of the etching processes and/or etching steps, the air spacers AS are formed with the dimensions that are positively related to the dimensions of the corresponding inner spacers 127, that is, the larger the dimension of the inner spacer 127, the larger the dimension of the air spacer AS. As a result, the parasitic capacitance may be reduced as much as possible while avoiding breaking through of the inner spacers by subsequent etching.

In some embodiments, the air spacers AS have symmetrical profiles, such as circular or elliptical profiles. In some embodiments, the major axes (or symmetry symmetric axes) of the elliptical profiles of the air spacers AS_1, AS_2 and AS_3 extend in the Z direction, and are not aligned with one another.

For example, the major axis LA1 of the elliptical profile of the air spacer AS_1 is located within the inner spacer 127_1, and does not exceed the unrecessed surfaces 127S2, in accordance with some embodiments. The major axis LA3 of the elliptical profile of the air spacer AS_3 is located outside the inner spacer 127_3, and exceeds at least one of the unrecessed surfaces 127S2, in accordance with some embodiments. The major axis LA2 of the elliptical profile of the air spacer AS_2 is located between the extension lines of the major axis LA1 and the major axis LA3, in accordance with some embodiments. In some embodiments, the major axis LA2 is aligned with the unrecessed surface 127S2 of the sidewall of the inner spacer 127_2.

FIGS. 2H-1 and 2H-2 are cross-sectional views of the semiconductor structure 100 after the formation of a contact etching stop layer (CESL) 134 and an interlayer dielectric layer 136 corresponding to line X-X and line Y2-Y2 of FIG. 1, in accordance with some embodiments of the disclosure. FIG. 2H-3 is a plan view of the semiconductor structure 100 taken along plan I-I in FIG. 2H-1.

A contact etching stop layer 134 is formed over the semiconductor structure 100 to cover the source/drain features 132, as shown in FIGS. 2H-1 to 2H-3, in accordance with some embodiments. The contact etching stop layer 134 is further formed along, and covers, the sidewalls of the gate spacers 118, the top and sidewalls of the fin spacers 120, and the top surface of the isolation structure 110, in accordance with some embodiments. Afterward, an interlayer dielectric layer 136 is formed over the contact etching stop layer 134, as shown in FIGS. 2H-1 to 2H-3, in accordance with some embodiments.

In some embodiments, the contact etching stop layer 134 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 134 is globally and conformally deposited over the semiconductor structure 100 using CVD (such as LPCVD, PECVD, HDP-CVD, or HARP), ALD, another suitable method, or a combination thereof.

In some embodiments, the interlayer dielectric layer 136 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), or another suitable dielectric material.

In some embodiments, the interlayer dielectric layer 136 and the contact etching stop layer 134 are made of different materials and have a great difference in etching selectivity. In some embodiments, the dielectric material for the interlayer dielectric layer 136 is deposited using such as CVD (such as HDP-CVD, PECVD, HARP or FCVD), another suitable technique, or a combination thereof. The dielectric materials for the contact etching stop layer 134 and the interlayer dielectric layer 136 above the top surface of the dummy gate electrode layer 116 are removed using such as CMP, in accordance with some embodiments.

FIGS. 2I-1 and 2I-2 are cross-sectional views of the semiconductor structure 100 after the formation of gate trench 138 and gaps 140 corresponding to line X-X and line Y1-Y1 of FIG. 1, in accordance with some embodiments of the disclosure. FIG. 2I-3 is a plan view of the semiconductor structure 100 taken along plan I-I in FIG. 2I-1.

The dummy gate structure 112 is removed using an etching process to form gate trench 138 between the gate spacers 118, as shown in FIGS. 2I-1 and 2I-2, in accordance with some embodiments. In some embodiments, the gate trench 138 exposes the channel region of the active region 104 and the top surface of the isolation structure 110. In some embodiments, the gate trench 138 further exposes the sidewalls of the gate spacers 118 facing the channel region. In some embodiments, the etching process includes one or more etching processes. For example, when the dummy gate electrode layer 116 is made of polysilicon, a wet etchant such as a tetramethylammonium hydroxide (TMAH) solution may be used to selectively remove the dummy gate electrode layer 116. For example, the dummy gate dielectric layer 114 may be thereafter removed using a plasma dry etching, a dry chemical etching, and/or a wet etching.

Afterward, an etching process is performed to remove the first semiconductor layers 106, thereby forming gaps 140, as shown in FIGS. 2I-1 to 2I-3, in accordance with some embodiments. The gaps 140 are formed between adjacent second semiconductor layers 108 and between the bottommost semiconductor layer 108 and the lower fin element 104L, in accordance with some embodiments. In some embodiments, the gaps 140 also expose the sidewalls of the inner spacers 127 facing the channel region.

The inner spacers 127 may be used as an etching stop layer in the etching process, which may protect the source/drain features 132 from being damaged. If the minimum width (e.g., D4) of the inner spacers 127 is less than about 3 nm the risk that the inner spacers are broken in the etching process may increase. In accordance with the embodiments of the present disclosure, the dimension of the air spacer AS may be adjusted according to the dimension of the corresponding inner spacer 127, which may achieve a better balance between reducing the parasitic capacitance and avoiding breaking through the inner spacer. Therefore, the performance and the yield of the resulting semiconductors devices may improve.

In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions. In some embodiments, a corner-rounding process may be optionally performed on the nanostructures 108.

In some embodiments, the gaps 140 are denoted as 140_1, 140_2 and 140_3 from top to bottom. The dimensions of the gaps 140 in the X direction may be substantially the same as the lengths (i.e., L1, L2 and L3) of the first semiconductor layer 106.

After the one or more etching processes, four main surfaces of the second semiconductor layers 108 are exposed, in accordance with some embodiments. The exposed second semiconductor layers 108 form nanostructures, in accordance with some embodiments. The nanostructures 108 are vertically stacked and spaced apart from one other, in accordance with some embodiments. The nanostructures 108 function as channels of the resulting semiconductor devices (e.g., nanostructure transistors such as GAA transistors), in accordance with some embodiments.

FIGS. 2J-1, 2J-2 and 2J-3 are cross-sectional views of the semiconductor structure 100 after the formation of a final gate stack 142 corresponding to line X-X, line Y1-Y1 and line Y2-Y2 of FIG. 1, in accordance with some embodiments of the disclosure. FIG. 2J-4 is a plan view of the semiconductor structure 100 taken along plan I-I in FIG. 2J-1.

A final gate stack 142 is formed in the gate trench 138 and gaps 140, as shown in FIGS. 2J-1, 2J-2 and 2J-4, in accordance with some embodiments. The nanostructures 108 are wrapped by the final gate stack 142, in accordance with some embodiments. In some embodiments, the final gate stack 142 extends in the Y direction. The final gate stack 142 has a longitudinal axis parallel to the Y direction, in accordance with some embodiments.

The final gate stack 142 engages the channel region so that current can flow between the source/drain features 132 during operation. In some embodiments, each of the final gate stack 142 includes an interfacial layer 144, a gate dielectric layer 146 and a metal gate electrode layer 148, as shown in FIGS. 2J-1, 2J-2 and 2J-4, in accordance with some embodiments.

The interfacial layer 144 is formed on the exposed surfaces of the nanostructures 108 and the lower fin element 104L, in accordance with some embodiments. The interfacial layer 144 wraps around the nanostructures 108, in accordance with some embodiments. In some embodiments, the interfacial layer 144 is made of a chemically formed silicon oxide. In some embodiments, the interfacial layer 144 is nitrogen-doped silicon oxide. In some embodiments, the interfacial layer 144 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin element 104L is oxidized to form the interfacial layer 144, in accordance with some embodiments.

The gate dielectric layer 146 is formed conformally along the interfacial layer 144 to wrap around the nanostructures 108, in accordance with some embodiments. The gate dielectric layer 146 is also conformally formed along the sidewalls of the gate spacers 118 facing the channel region, in accordance with some embodiments. The gate dielectric layer 146 is also conformally formed along the sidewalls of the inner spacers 127 facing the channel region, in accordance with some embodiments. The gate dielectric layer 146 is further formed along the top surface of the isolation structure 110, in accordance with some embodiments.

The gate dielectric layer 146 may be high-k dielectric layer. In some embodiments, the high-k dielectric layer is dielectric material with high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), a combination thereof, or another suitable material. The high-k dielectric layer may be deposited using ALD, PVD, CVD, or another suitable technique.

The metal gate electrode layer 148 is formed to overfill remainders of the gate trench 138 and gaps 140, in accordance with some embodiments. In some embodiments, the metal gate electrode layer 148 is made of more than one conductive material, such as a metal, metal alloy, conductive metal oxide and/or metal nitride, another suitable conductive material, and/or a combination thereof. For example, the metal gate electrode layer 148 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 148 may be a multi-layer structure with various layer combinations of a diffusion barrier layer, a work function layer with a selected work function to enhance the device's performance (e.g., threshold voltage) for n-channel FETs or p-channel FETs, a capping layer to prevent oxidation of the work function layers, a glue layer to adhere the work function layer to the next layer, and a metal fill layer to reduce the total resistance of gate stacks, and/or another suitable layer. The metal gate electrode layer 148 may be formed using ALD, PVD, CVD, e-beam evaporation, or another suitable technique.

A planarization process such as CMP may be performed on the semiconductor structure 100 to remove the materials of the gate dielectric layer 146 and the metal gate electrode layer 148 formed above the top surface of the interlayer dielectric layer 136, in accordance with some embodiments. The final gate stack 142 that are wrapped around the nanostructures 108 combine with the neighboring source/drain features 132 to form nanostructure transistors, e.g., n-channel nanostructure transistors and p-channel nanostructure transistors.

In some embodiments, the final gate stack 142 formed between the nanostructures 108 and between the bottommost nanostructure 108 and the lower fin element 104 are referred to as inner gates IG. The inner gates IG are denoted as IG_1, IG_2 and IG_3 from top to bottom. The lengths of the inner gates IG in the X direction may be substantially the same as the lengths (i.e., L1, L2 and L3) of the first semiconductor layer 106. In some embodiments, in the X direction, the length L1 of the inner gate IG1 is less than the length L2 of the inner gate IG2, and the length L2 is less than the length L3 of the inner gate IG3. That is, the dimensions of the inner gates IG in the X direction increase as the level of the inner gate IG decreases from top to bottom, in accordance with some embodiments.

Because the bottommost inner gates IG_3 has a longer length, the inner gates IG_3 has better gate control over the lower fin element 104L that is used as the channel for the bottom planar transistor, thereby reducing the leakage of the resulting semiconductor devices.

It is understood that the semiconductor structure 100 may undergo further CMOS processes to form various features over the semiconductor structure 100, such as contact plugs to gate and/or to source/drain features, vias, lines, inter metal dielectric layers, passivation layers, etc.

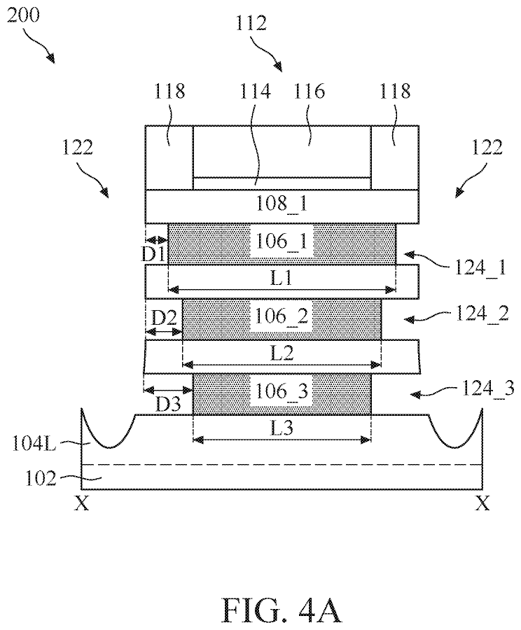

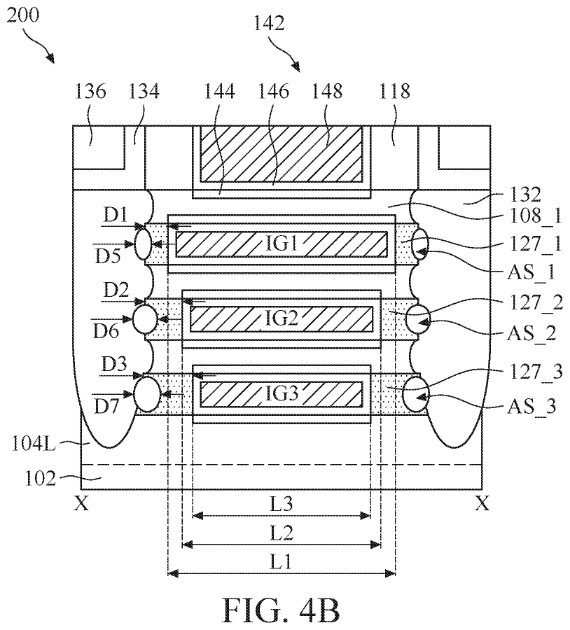

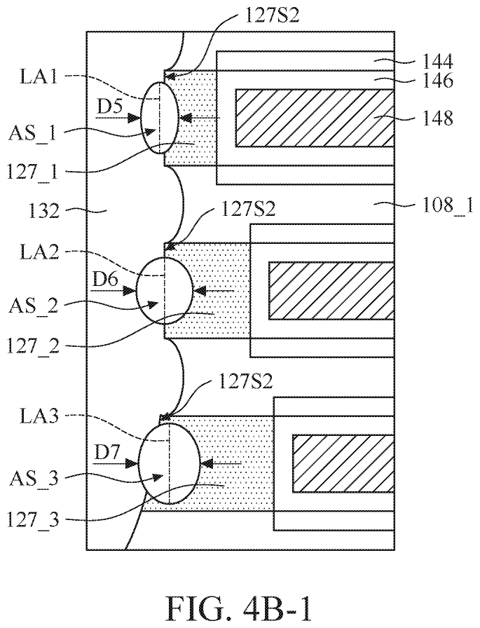

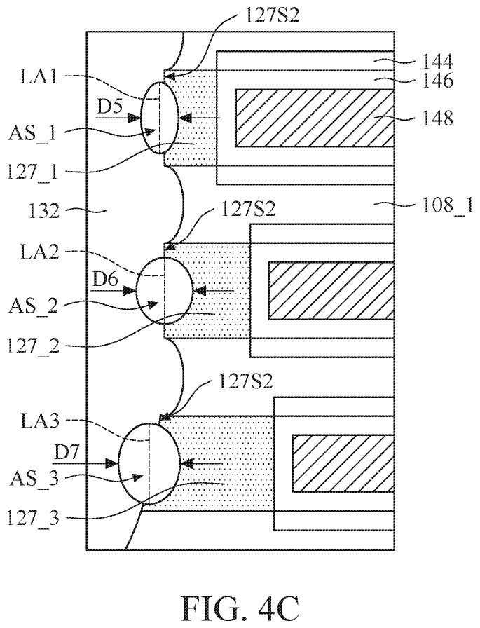

FIGS. 4A and 4B are cross-sectional views illustrating the formation of a semiconductor structure 200 at various intermediate stages. The embodiments of FIGS. 4A and 4B are similar to the embodiments of the FIGS. 2A-1 through 2J-4, except that the semiconductor structure 200 is used to form high performance devices.

FIG. 4A illustrates the semiconductor structure 200 after an etching process for forming notches 124 corresponding to line X-X of FIG. 1.

Continuing from FIGS. 2B-1 to 2B-3, an etching process is performed to laterally recess, from the source/drain recesses 122 toward the channel region, the first semiconductor layers 106 of the fin structure 104 to form notches 124, in accordance with some embodiments. In some embodiments, in the X direction, the width D1 (or recessing depth) of the notch 124_1 is less than the width D2 (or recessing depth) of the notch 124_2, and the width D2 (or recessing depth) is less than the width D3 (or recessing depth) of the notch 124_3. That is, the dimensions of the notches 124 in the X direction increase as the level of the first semiconductor layers 106 decreases from top to bottom, in accordance with some embodiments.

In some embodiments, in the X direction, the length L1 of the first semiconductor layer 106_1 is greater than the length L2 of the first semiconductor layer 106_2, and the length L2 is greater than the length L3 of the first semiconductor layer 106_3. That is, the dimensions of the first semiconductor layers 106_1 in the X direction decreases as the level of the first semiconductor layer 106 decreases from top to bottom, in accordance with some embodiments.

FIG. 4B illustrates the semiconductor structure 200 after the formation of the final gate stack 142 corresponding to line X-X of FIG. 1.

The steps described above in FIGS. 2D-1 to 2J-4 are performed, thereby forming the inner spacers 127, the air spacers AS, the source/drain features 132, the contact etching stop layer 134, the interlayer dielectric layer 136 and the final gate stacks 142, in accordance with some embodiments.

In some embodiments, in the X direction, the maximum width D1 of the inner spacer 127_1 is less than the maximum width D2 of the inner spacer 127_2, and the maximum width D2 is less than the maximum width D3 of the inner spacer 127_3. That is, the maximum width of the inner spacers 127 increase as the level of the inner spacer 127 decreases from top to bottom, in accordance with some embodiments.

In some embodiments, in the X direction, the dimension D5 of the air spacer AS_1 is less than the dimension D6 of the air spacer AS_2, and the dimension D6 is less than the dimension D7 of the air spacer AS_3. That is, the dimensions of the air spacers AS in the X direction increases as the level of the air spacer AS decreases from top to bottom, in accordance with some embodiments. Such a dimension variation of the air spacers AS at different positions can be adjusted by adjusting the parameters (e.g., source/bias RF power, gas flow rate, pressure, etc.) of the etching process for forming the recesses 130.

In accordance with the embodiments of the present disclosure, by adjusting the parameters of the etching processes and/or etching steps, the air spacers AS are formed with the dimensions that are positively related to the dimensions of the inner spacers 127. As a result, a better balance may be achieved between reducing the parasitic capacitance and avoiding breaking through the inner spacer. Therefore, the performance and the yield of the resulting semiconductors devices may improve.

In some embodiments, in the X direction, the length L1 of the inner gate IG1 is greater than the length L2 of the inner gate IG2, and the length L2 is greater than the length L3 of the inner gate IG3. That is, the dimensions of the inner gates IG in the X direction decreases as the level of the inner gate IG decreases from top to bottom, in accordance with some embodiments.

Because the topmost inner gates IG_1 has a longer length, the inner gates IG_1 has better gate control over the topmost nanostructures 108, thereby enhancing the performance of the resulting semiconductor devices.

FIG. 4B-1 is an enlarged view of FIG. 4B to illustrate more detail of the air spacers AS, in accordance with some embodiments of the disclosure.

In some embodiments, the air spacers AS have symmetrical profiles, such as circular or elliptical profiles. The major axis LA1 of the elliptical profile of the air spacer AS_1 is located outside the inner spacer 127_1, and exceed the unrecessed surface 127S2, in accordance with some embodiments. The major axis LA3 of the elliptical profile of the air spacer AS_3 is located within the inner spacer 127_3, and does not exceed the unrecessed surface 127S2, in accordance with some embodiments. The major axis LA2 of the elliptical profile of the air spacer AS_2 is located between the extension lines of the major axis LA1 and the major axis LA3, in accordance with some embodiments. In some embodiments, the major axis LA2 is aligned with the unrecessed surface 127S2 of the sidewall of the inner spacer 127_2.

FIG. 4C is a modification of the cross-sectional view of FIG. 4B, in accordance with some embodiments of the disclosure. The major axis LA3 of the elliptical profile of the air spacer AS_3 is located outside the inner spacer 127_3, and exceeds at least one of the unrecessed surfaces 127S2, in accordance with some embodiments. The major axis LA1 of the elliptical profile of the air spacer AS_1 is located between the extension lines of the major axis LA2 and the major axis LA3, in accordance with some embodiments.

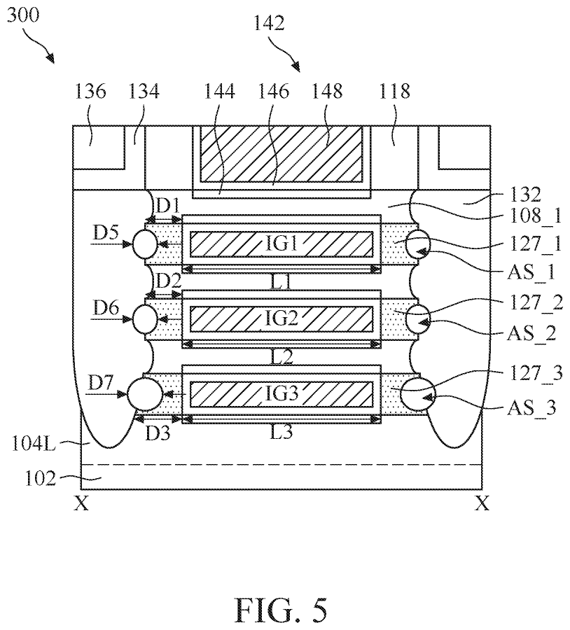

FIG. 5 is a cross-sectional view of a semiconductor structure 300, in accordance with some embodiments of the disclosure. The embodiments of FIG. 5 are similar to the embodiments of the FIGS. 2A-1 through 2J-4, except that the dimensions of the inner gates IG in the X direction keep constant as the level of the inner gate IG decreases from top to bottom, in accordance with some embodiments.

In some embodiments, in the X direction, the maximum width D1 of the inner spacer 127_1 is substantially the maximum width D2 of the inner spacer 1272, and the maximum width D3 of the inner spacer 127_3 is greater than the maximum widths D1 and D2.

In some embodiments, in the X direction, the dimension D5 of the air spacer AS_1 is substantially the same as the dimension D6 of the air spacer AS_2, and the dimension D7 of the air spacer AS_3 is greater than the dimensions D5 and D6.

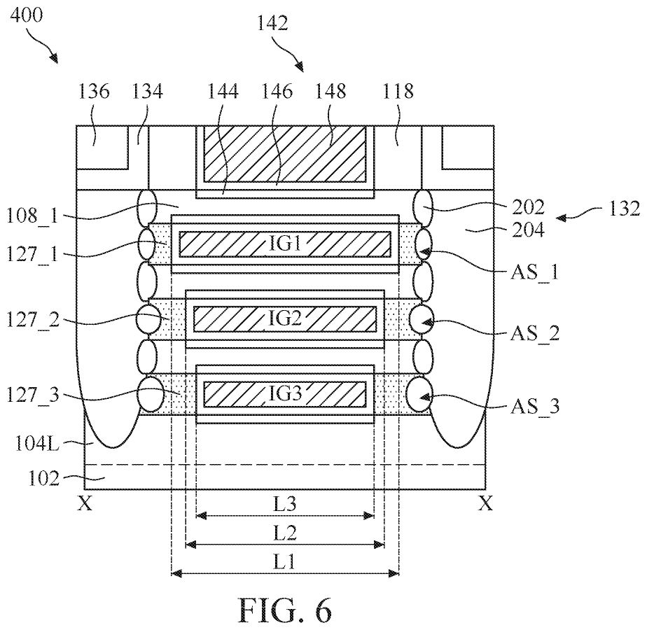

FIG. 6 is a cross-sectional view of a semiconductor structure 400, in accordance with some embodiments of the disclosure. The embodiments of FIG. 6 are similar to the embodiments of the FIGS. 2A-1 through 2J-4, except that the source/drain features 132 include multilayered structures.

In some embodiments, the source/drain feature 132 includes barrier layers 202 formed on the exposed second semiconductor layers 108 and a bulk layer 204 filling the remainder of the source/drain recess 122 (FIG. 2B-1). In some embodiments, the barrier layer 202 and the bulk layer 204 are doped epitaxial materials, and the concentration of the dopant in the bulk layer 204 is higher than the concentration of the dopant in the barrier layers 202, e.g., by 1-2 orders. The barrier layers 202 are spaced apart from the air spacers AS by the bulk layers 204, in accordance with some embodiments.

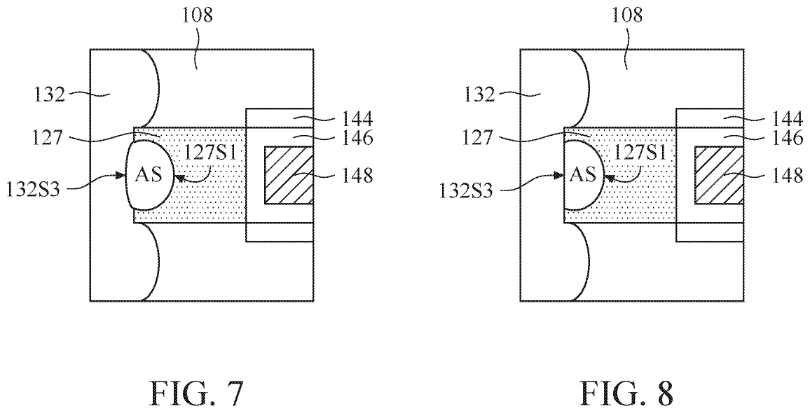

FIGS. 7 and 8 are cross-sectional views of air spacers AS and neighboring components, in accordance with some embodiments of the disclosure. The embodiments of FIGS. 7 and 8 are similar to the embodiments of the FIGS. 2A-1 through 2J-4, except that the air spacers AS have asymmetrical profiles.

In some embodiments, the recessed surface 127S1 of the inner spacer 127 exposed from the air spacer AS has a first radius of curvature, and the third surface 132S3 of the source/drain feature 132 exposed from the air spacer AS has a second radius of curvature that is greater than the first radius of curvature, as shown in FIG. 7. In some embodiments, the third surface 132S3 of the source/drain feature 132 may be substantially flat, and vertically extends, as shown in FIG. 8.

As described above, the semiconductor structure and the method for forming the semiconductor structure are provided. The semiconductor structure may include the inner spacer 127, the source/drain feature 132 and the air spacer AS sealed by the inner spacer 127 and the source/drain feature 132. The air spacers may further reduce the parasitic capacitance between the final gate stack 142 and the source/drain features 132.

In addition, by adjusting the parameters of the etching processes and/or etching steps for forming the inner spacer 127 and the source/drain features 132, the air spacers AS may be formed with the dimensions that are positively related to the dimensions of the corresponding inner spacers 127. As a result, a better balance may be achieved between reducing the parasitic capacitance and avoiding breaking through the inner spacer. Therefore, the performance and the yield of the resulting semiconductors devices may improve.

Embodiments of a semiconductor structure and the method for forming the same may be provided. The semiconductor structure may include an air spacer sealed between an inner spacer and a source/drain feature. The air spacer exposes the sidewall of the inner spacer and the sidewall of the source/drain feature. Therefore, the parasitic capacitance may reduce, and thus the performance of the resulting semiconductor devices may improve.

In some embodiments, a method for forming a semiconductor structure is provided. The method includes forming a fin structure over a substrate. The fin structure includes alternatingly stacked first semiconductor layers and second semiconductor layers. The method also includes laterally recessing the first semiconductor layers of the fin structure to form a plurality of notches, forming a plurality of inner spacers in the plurality of notches, laterally recessing the plurality of inner spacers to form a plurality of recesses in the plurality of inner spacers, and growing a source/drain feature over the fin structure. The plurally of recesses are sealed by the source/drain feature and the plurality of inner spacers to form a plurality of air spacers.

In some embodiments, a method for forming a semiconductor structure is provided. The method includes forming a stack in which two channel layers are interposed by a sacrificial layer, patterning the stack into a fin structure, etching the fin structure to form a source/drain recess, laterally recessing the sacrificial layer to form a notch, and forming an inner spacer in the notch. The inner spacer has a first recess. The method further includes etching the inner spacer to enlarge the first recess, thereby forming an enlarged recess, forming a source/drain feature in the source/drain recess, thereby sealing the enlarged recess to form an air spacer, removing the sacrificial layer, and forming a gate stack surrounding the channel layers.

In some embodiments, a semiconductor structure is provided. The semiconductor structure includes a plurality of nanostructures, a source/drain feature adjoining the plurality of nanostructures, a gate stack surrounding the nanostructures, and a plurality of inner spacers between the gate stack and the source/drain feature. A first air spacer is sealed between a first inner spacer in the plurality of inner spacers and the source/drain feature. The first air spacer exposes a surface of the first inner spacer and a surface of the source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a fin structure over a substrate, wherein the fin structure includes alternatingly stacked first semiconductor layers and second semiconductor layers;
laterally recessing the first semiconductor layers of the fin structure to form a plurality of notches;
forming a plurality of inner spacers in the plurality of notches;
laterally recessing the plurality of inner spacers to form a plurality of recesses in the plurality of inner spacers; and
growing a source/drain feature over the fin structure, wherein the plurally of recesses are sealed by the source/drain feature and the plurality of inner spacers to form a plurality of air spacers.

2. The method of claim 1, wherein the plurality of inner spacers includes a first inner spacer, a second inner spacer and a third inner spacer which are arranged from top to bottom, a first width of the first inner spacer is greater than a second width of the second inner spacer, and the second width of the second inner spacer is greater than a third width of the third inner spacer.

3. The method of claim 2, wherein the plurality of recesses includes a first recess, a second recess and a third recess which are formed in the first inner spacer, the second inner spacer and the third inner spacer respectively, a first width of the first recess is greater than a second width of the second recess, and the second width of the second recess is greater than a third width of the third recess.

4. The method of claim 1, further comprising:
laterally recessing the second semiconductor layers of the fin structure while laterally recessing the plurality of inner spacers.

5. The method of claim 4, wherein the second semiconductor layers are laterally recessed to form concave sidewalls, and the source/drain feature has convex surfaces interfaced and mated with the concave sidewalls of the second semiconductor layers.

6. The method of claim 1, wherein the source/drain feature has concave surfaces exposed from the air spacers, respectively.

7. The method of claim 1, wherein growing the source/drain feature comprises repeating steps of:
depositing an epitaxial material on sidewalls of the second semiconductor layers and on sidewalls of the inner spacers; and
etching the epitaxial material until the sidewalls of the inner spacers are exposed.

8. The method of claim 7, wherein the epitaxial material deposited on neighboring two of the second semiconductor layers merges with each other.

9. A method for forming a semiconductor structure, comprising:
forming a stack in which two channel layers are interposed by a sacrificial layer;
patterning the stack into a fin structure;
etching the fin structure to form a source/drain recess;
laterally recessing the sacrificial layer to form a notch;
forming an inner spacer in the notch, the inner spacer having a first recess;
etching the inner spacer to enlarge the first recess, thereby forming an enlarged recess;
forming a source/drain feature in the source/drain recess, thereby sealing the enlarged recess to form an air spacer;
removing the sacrificial layer; and
forming a gate stack surrounding the channel layers.

10. The method of claim 9, wherein forming the source/drain feature in the source/drain recess comprises:
partially filling an epitaxial material in the enlarged recess; and
removing the epitaxial material from the enlarged recess.

11. The method of claim 9, wherein forming the source/drain feature in the source/drain recess comprises:
growing barrier layers on the sidewalls of the channel layers; and
growing a bulk layer on the barrier layers, wherein a dopant concentration of the bulk layer is greater than a dopant concentration of the barrier layers.

12. The method of claim 11, wherein the barrier layers are separated from the air spacer by the bulk layer.

13. The method of claim 11, further comprising:
laterally recessing the channel layers to form second recesses in the channel layers, wherein the source/drain features fill the second recesses.

14. A semiconductor structure, comprising:
a plurality of nanostructures;
a source/drain feature adjoining the plurality of nanostructures;
a gate stack surrounding the nanostructures; and
a plurality of inner spacers between the gate stack and the source/drain feature, wherein a first air spacer is sealed between a first inner spacer in the plurality of inner spacers and the source/drain feature, and the first air spacer exposes a surface of the first inner spacer and a surface of the source/drain feature.

15. The semiconductor structure of claim 14, wherein a second air spacer is sealed between a second inner spacer in the plurality of inner spacers and the source/drain feature, wherein a dimension of the second inner spacer is greater than a dimension of the first inner spacer in a first direction, and a dimension of the second air spacer is greater than a dimension of the first air spacer in the first direction.

16. The semiconductor structure of claim 15, wherein the first air spacer has a first elliptical profile, the second air spacer has a second elliptical profile, a first major axis of the first elliptical profile and a second major axis of the second elliptical profile extend in a vertical direction, and an extension line of the first major axis is staggered from an extension line of the second major axis.

17. The semiconductor structure of claim 14, further comprising:
a gate spacer alongside the gate stack, wherein the gate spacer surrounds the first inner spacer.

18. The semiconductor structure of claim 14, wherein a portion of the surface of the first inner spacer exposed from the first air spacer is a first concave surface, and a portion of the surface of the source/drain feature exposed from the first air spacer is a second concave surface.

19. The semiconductor structure of claim 18, wherein a portion of the surface of the first inner spacer exposed from the first air spacer has a first radius of curvature, and a portion of the surface of the source/drain feature exposed from the first air spacer has a second radius of curvature that is greater than the first radius of curvature.

20. The semiconductor structure of claim 14, wherein the source/drain feature has a side surface interfaced with a first nanostructure in the plurality of nanostructures, and the side surface of the source/drain feature is convex.
